(19) United States
(12) Patent Application Publication
(10) Pub. No.: US 2016/0173667 A1
(43) Pub. Date: Jun. 16, 2016

(54) MAGNETIC MOBILE PHONE MOUNTING KIT

(71) Applicants: Bernardino Ruben Torres Gutierrez, Los Angeles, CA (US); Juan Carlos Morales Lopez, Santa Monica, CA (US)

(72) Inventors: Bernardino Ruben Torres Gutierrez, Los Angeles, CA (US); Juan Carlos Morales Lopez, Santa Monica, CA (US)

(21) Appl. No.: 14/568,028

(22) Filed: Dec. 11, 2014

(51) Int. Cl. H04M 1/02; H05K 7/18; H02J 7/00; H04M 1/04

(52) U.S. Cl. CPC H04M 1/0266; H04M 1/04; H05K 7/186; H02J 7/0044; H02J 7/0045; H02J 7/0054

(57) ABSTRACT

A mobile phone mounting kit. The mobile phone mounting kit may comprise: a case, magnetic mounting platform, vehicle mounting arm, and air vent clips. The magnetic mounting platform may attach to a first end of the vehicle mounting arm, and the second end of the vehicle mounting arm may comprises a suction cup for attaching onto a surface. The magnetic mounting platform may comprises a magnet. The case may be configured to house a mobile phone and comprises one or more metal plates for attaching and securing to the magnet of the magnetic mounting platform. The case may comprises: a charging port, wires, charging contacts; and metal plates. The charging contacts may electrically communicate with a battery of the mobile phone. The charging port may mate and engage a connector of a power cable for charging the mobile phone by transferring an electrical current from the charging port to the charging contacts via the wires. The magnetic mounting platform may comprise a solar panel and a battery, wherein the solar panel may charge the battery of the mobile phone. The solar panel may be in electrical communication with the battery of the magnetic mounting platform. The air vent clips may removeably attach the magnetic mounting platform to an air vent of vehicle. The mobile phone mounting kit may further comprise a holster, which may include: a clip and a magnet for mounting and securing the case and magnetic mounting platform to a user's belt.

### FIELD OF USE

The present disclosure relates generally to mobile phone accessories, and, in particular, to mobile phone accessories that may allow a user to hold, secure, and/or charge his or her mobile phone.

### BACKGROUND

Driver distractions have always been an important risk factor affecting auto collisions. Examples of such driving distractions may include: eating and drinking, tuning the radio, viewing billboards, and talking to passengers. Accordingly, one way to eliminate driver distractions is to recommend that the driver put both hands on the steering wheel at all times while driving.

One very common distraction that has been significantly increasing in importance over the past several years is the use of a cellular phone or smartphone (mobile phone) while driving. Many drivers, especially those carrying smartphones, use their mobile phone while driving. Such use may include surfing the web, texting, checking emails, and calling others, often without the use of a handsfree accessory. Use of the mobile phone while driving has become increasingly popular due to the rise in dependence on the mobile phone as a primary source for communication and entertainment. Due to the visual demand and cognitive attention required when using a mobile phone, mobile phone use has become the most alarming distraction that drivers face. As a result, mobile phone use while driving has been banned in most states.

To reduce the risk of auto collisions relating to mobile phone use, various handsfree devices have been developed to allow drivers to communicate and minimize the need for the driver to use his or her hands to operate the mobile phone (e.g., voice commands) while driving, For example, many handsfree devices generally include a microphone, speaker, and Bluetooth® capability to allow the driver to speak and listen while driving with his or her hands on the wheel. Unfortunately, these handsfree devices do not provide charging capabilities for the mobile phone and are usually quite cumbersome when docking and holding the mobile phone.

Additionally, these handsfree devices generally do not allow ease of interoperability with other accessories, For instance, most mobile phone accessories generally do not include a case or a holster directed to particular docking station. This may prevent the person from easily switching his or her mobile phone from a holster to the vehicle docking station.

Therefore, there remains along felt need in the art for a mobile phone mounting kit that overcomes the above deficiencies. Preferably, the mobile phone mounting kit can be used to easily hold and secure a mobile phone to the user or vehicle and/or electrically charge the phone when holding and securing the mobile phone.

### SUMMARY OF ILLUSTRATIVE EMBODIMENTS

To minimize the limitations in the cited references, and to minimize other limitations that will become apparent upon reading and understanding the present specification, the following discloses a mobile phone mounting kit for allowing a user to mount, hold, secure, and/or charge his or her mobile phone.

One embodiment of the mobile phone mounting kit may comprise: a case; a magnetic mounting platform; and a vehicle mounting arm; wherein the magnetic mounting platform is configured to removeably attach to a first end of the vehicle mounting arm; wherein the second end of the vehicle mounting arm comprises a device for attaching to a surface; wherein the magnetic mounting platform comprises at least one magnet; and wherein the case is configured to removeably engage with a mobile phone and comprises one or more metal plates for attaching and securing to the at least one magnet of the magnetic mounting platform, such that the case securely but removeably attaches to the magnetic mounting platform. The case may further comprise: a charging port; one or more wires; and at least two first charging contacts; wherein a first end of the one or more wires may be coupled to the charging port; wherein a second end of the one or more wires may be coupled to the at least two first charging contacts; wherein the at least two first charging contacts may be configured to couple with a battery of the mobile phone when the case is engaged with the mobile phone, such that the at least two first charging contacts may be in electrical communication with the battery of the mobile phone; and wherein the charging port may be configured to matingly engage with a connector of a power cable for charging the mobile phone by transferring an electrical current from the charging port to the at least two first charging contacts via the one or more wires. The magnetic mounting platform may further comprise a battery; wherein the battery of the magnetic mounting platform may comprise at least two second charging contacts; wherein the at least two second charging contacts may be configured to couple with the at least two first charging contacts of the case when the case is mounted on the magnetic mounting platform, such that the at least two second charging contacts may be in electrical communication with the at least two first charging contacts; and wherein the battery of the magnetic mounting platform may be configured to store an electrical charge for the mobile phone. The magnetic mounting platform may further comprise a solar panel; wherein the solar panel may be positioned at a rear side of the magnetic mounting platform and may be in electrical communication with the battery of the magnetic mounting platform, such that the solar panel may be configured to charge the battery of the magnetic mounting platform. The mobile phone mounting kit of claim 1, wherein the surface may be an air vent of a vehicle dashboard; wherein the device for attaching to the surface may be one or more air vent clips; wherein a distal end of the one or more air vent clips may be configured to removeably attach to the vehicle mounting arm; and wherein a proximal end of the one or more air vent clips may be configured to removeably attach to the air vent, such that the mobile phone may be mounted onto the air vent of the vehicle dashboard when the mobile phone is attached to the case and the magnetic mounting platform. The device for attaching to the surface may be a suction cup. Each of the one or more metal plates of the case may be between approximately 15 millimeters and 25 millimeters in length and between approximately 12 millimeters and 17 millimeters in width. The battery of the magnetic mounting platform may be between approximately 33 millimeters and 37 millimeters in width and between approximately 10 millimeters and 15 millimeters in thickness.

Another embodiment may be a mobile phone mounting kit, comprising: a case; a magnetic mounting platform; and a vehicle mounting arm; wherein the magnetic mounting platform is configured to removeably attach to a first end of the vehicle mounting arm; wherein the second end of the vehicle mounting arm comprises a device for attaching to a surface; wherein the magnetic mounting platform comprises at least one magnet; wherein the case is configured to removeably engage with a mobile phone and comprises one or more metal plates for attaching and securing to the at least one magnet of the magnetic mounting platform, such that the case securely but removeably attaches to the magnetic mounting platform; and wherein at least one of the one or more metal plates are hidden within the case. The case may comprise: a charging port; one or more wires; and at least two first charging contacts; wherein a first end of the one or more wires may be coupled to the charging port; wherein a second end of the one or more wires may be coupled to the at least two first charging contacts; wherein the at least two first charging contacts may be configured to couple with a battery of the mobile phone when the case is engaged with the mobile phone, such that the at least two first charging contacts may be in electrical communication with the battery of the mobile phone; wherein the charging port may be configured to matingly engage with a connector of a power cable for charging the mobile phone by transferring an electrical current from the charging port to the at least two first charging contacts via the one or more wires; and wherein the one or more wires may be hidden within the case. The magnetic mounting platform may further comprise a battery; wherein the battery of the magnetic mounting platform may comprise at least two second charging contacts; wherein the at least two second charging contacts may be configured to couple with the at least two first charging contacts of the case when the case is mounted on the magnetic mounting platform, such that the at least two second charging contacts may be in electrical communication with the at least two first charging contacts; and wherein the battery of the magnetic mounting platform may be configured to store an electrical charge for the mobile phone. The magnetic mounting platform may further comprise a solar panel; wherein the solar panel may be positioned at a rear side of the magnetic mounting platform and may be in electrical communication with the battery of the magnetic mounting platform, such that the solar panel may be configured to charge the battery of the magnetic mounting platform. The surface may be an air vent of a vehicle dashboard; wherein the device for attaching to the surface may be one or more air vent clips; wherein a distal end of the one or more air vent clips may be configured to removeably attach to the vehicle mounting arm; and wherein a proximal end of the one or more air vent clips may be configured to removeably attach to the air vent, such that the mobile phone may be mounted onto the air vent of the vehicle dashboard when the mobile phone is attached to the case and the magnetic mounting platform. The device for attaching to the surface may be a suction cup. The vehicle mounting arm may comprise a joint configured to move and adjust the vehicle mounting arm.

Another embodiment may be a mobile phone mounting kit, comprising: a case and a holster; wherein the holster may comprise a clip, at least one magnet, and a housing for the at least one magnet; wherein the clip may be configured to fasten onto a belt of a user; and wherein the case may be configured to removeably engage with a mobile phone and may comprise one or more metal plates for attaching and securing to the at least one magnet, such that the case securely but removeably attaches to the at least one magnet. The housing may be constructed of leather.

It is an object to provide a mobile phone mounting kit that allow a user to dock his or her mobile phone inside of a vehicle. In various embodiments, the user may dock his or her phone on the vehicle windshield/dashboard, vehicle air vent, or user's belt.

It is an object to provide a mobile phone mounting kit that allows a user to charge his mobile phone while the phone is docked or mounted.

It is an object to provide a mobile phone mounting kit that allows a user to charge his mobile phone via a solar panel.

It is an object to provide a mobile phone mounting kit that utilizes magnetism for mounting.

It is an object of the mobile phone mounting kit to overcome the limitations of the prior art.

Other features and advantages are inherent in the mobile phone mounting kit claimed and disclosed will become apparent to those skilled in the art from the following detailed description and its accompanying drawings.

### BRIEF DESCRIPTION OF THE DRAWINGS

The drawings are of illustrative embodiments. They do not illustrate all embodiments. Other embodiments may be used in addition or instead. Details which may be apparent or unnecessary may be omitted to save space or for more effective illustration. Some embodiments may be practiced with additional components or steps and/or without all of the components or steps which are illustrated. When the same numeral appears in different drawings, it refers to the same or like components or steps.

FIG. 1 is an illustration of one embodiment of a magnetic mobile phone mounting kit.

FIG. 2 is an illustration of a front elevational view of one embodiment of a case.

FIG. 3 is an illustration of a rear elevational view of one embodiment of a case.

FIG. 4 is an illustration of a front elevational view of one embodiment of the magnetic mounting platform.

FIG. 5 is an illustration of a rear perspective view of one embodiment of the magnetic mounting platform and vehicle mounting arm and shows the magnetic mounting platform attached to the vehicle mounting arm.

FIG. 6 is an illustration of one embodiment of the vehicle mounting arm with an air vent clip and shows how the mobile phone is mounted onto a vehicle dashboard via the magnetic mounting platform, vehicle mounting arm, and air vent clip.

FIG. 7 is an illustration of a front elevational view of one embodiment of a holster.

FIG. 8 is an illustration of a rear elevational view of one embodiment of a holster.

FIG. 9 is a schematic block diagram of the mobile phone mounting kit and shows the possible electrical connections among the mobile phone, case, magnetic mounting platform, and solar panel.

### DETAILED DESCRIPTION OF ILLUSTRATIVE EMBODIMENTS

In the following detailed description of various embodiments of the disclosure, numerous specific details are set forth in order to provide a thorough understanding of various aspects of one or more embodiments of the disclosure. However, one or more embodiments of the disclosure may be practiced without some or all of these specific details. In other instances, well-known methods, procedures, and/or components have not been described in detail so as not to unnecessarily obscure aspects of embodiments of the disclosure.

While multiple embodiments are disclosed, still other embodiments of the present disclosure will become apparent to those skilled in the art from the following detailed description, which shows and describes illustrative embodiments of the disclosure. As will be realized, the disclosure is capable of modifications in various obvious aspects, all without departing from the spirit and scope of the present disclosure. Accordingly, the graphs, figures, and the detailed descriptions thereof, are to be regarded as illustrative in nature and not restrictive. Also, the reference or non-reference to a particular embodiment of the disclosure shall not be interpreted to limit the scope of the disclosure.

Before the present disclosure is disclosed and described, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

In the following description, certain terminology is used to describe certain features of one or more embodiments of the disclosure. For example, a surface that is “substantially” flat would mean that the object is either completely flat or nearly completely flat. The exact allowable degree of deviation from absolute completeness may in some cases depend on the specific context. However, generally speaking, the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “mobile phone” generally refers to a telephone with access to a cellular radio system so it can be used over a wide area, without a physical connection to a network, including without limitation, cellular phones, smartphones, tablet computers, personal digital assistants (PDA), hand-held computers, and the like.

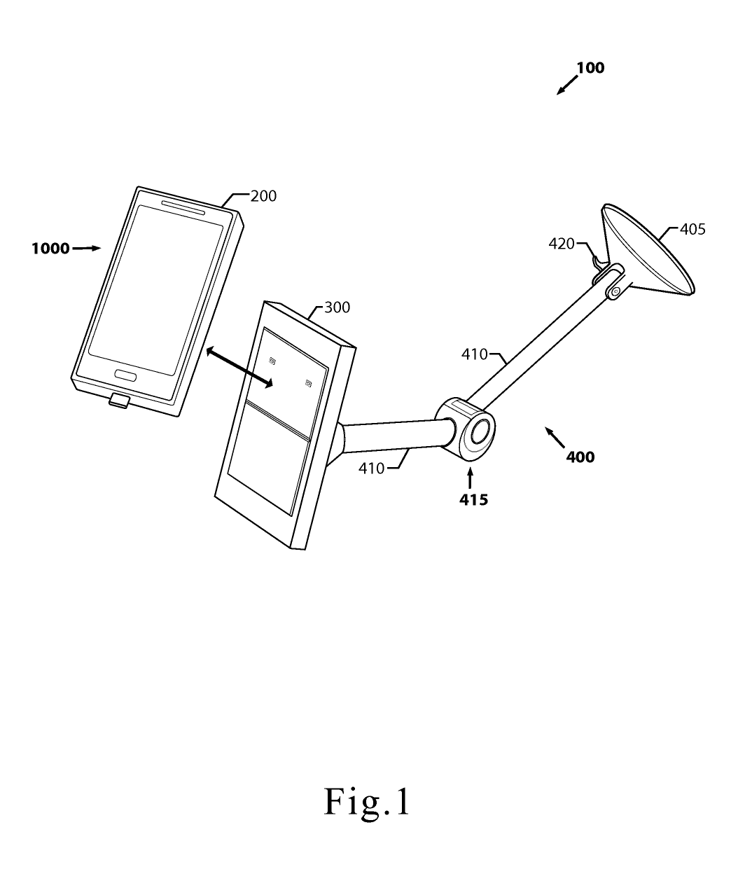

FIG. 1 is an illustration of one embodiment of a magnetic mobile phone mounting kit. As shown in FIG. 1, one embodiment of the magnetic mobile phone mounting kit 100 may comprise: a case 200, magnetic mounting platform 300, and a vehicle mounting arm 400. The case 200 may be an outer covering, housing, or receptacle for holding and protecting a mobile phone 1000 and may connect to the phone 1000 in a standard friction-based manner. The magnetic mounting platform 300 may be a base used to attach, hold, and secure the case 200, and may be attachable to and removeable from the vehicle mounting arm 400. The vehicle mounting arm 400 is preferably any structure configured to connect and hold the case 200 and mobile phone 1000 onto interior surface of a vehicle such as a dashboard a windshield.

FIG. 1 shows how a mobile phone 1000 such as a smartphone may mount onto a surface of a vehicle. Specifically, the vehicle mounting arm 400 may be used to attach to the windshield or dashboard of the vehicle. One embodiment of the vehicle mounting arm 400 may comprise: an arm 410, a hinge 415, and a device for attaching to a surface such as a suction cup 405. Specifically, the suction cup 405 is preferably attached to one end of the arm 410 and is preferably configured to mount or attach onto a windshield, dashboard, window, or other surface in the interior and front of a vehicle. The suction cup 405 may comprise a locking mechanism 420, which may be used to securely hold and mount the vehicle mounting arm 400 to a windshield or non-porous substantially flat surface. The vehicle mounting arm may also comprise a hinge 415 or joint, which may be used to move and adjust the vehicle mounting arm 400 at a particular angle. Preferably, the vehicle mounting arm 400 is constructed of rigid material such as polymers and/or metals, but may be flexible, bendable, and/or poseable, similar to gooseneck and/or snake arms. In one embodiment, the vehicle mounting arm 400 may be between approximately 15 centimeters and 30 centimeters in length, and, in a preferred embodiment, the vehicle mounting arm is approximately 22 centimeters in length. Although FIG. 1 shows that the vehicle mounting arm 400 comprises a hinge and locking mechanism, the vehicle mounting arm 400 may lack a hinge and/or locking mechanism in various embodiments. The vehicle mounting arm 400 may also be constructed of various lengths.

When the magnetic mounting platform 300 is attached to the second end of the vehicle mounting arm 400 via fasteners (e.g., hook fasteners), the magnetic mounting platform 300 is preferably adapted to attract and secure the case 200 of the mobile phone 1000. This preferably allows the case 200 and mobile phone 1000 to be securely held to the magnetic mounting platform 300 and the vehicle mounting arm 400, especially when the vehicle mounting arm 400 is attached to a windshield or dashboard of the vehicle.

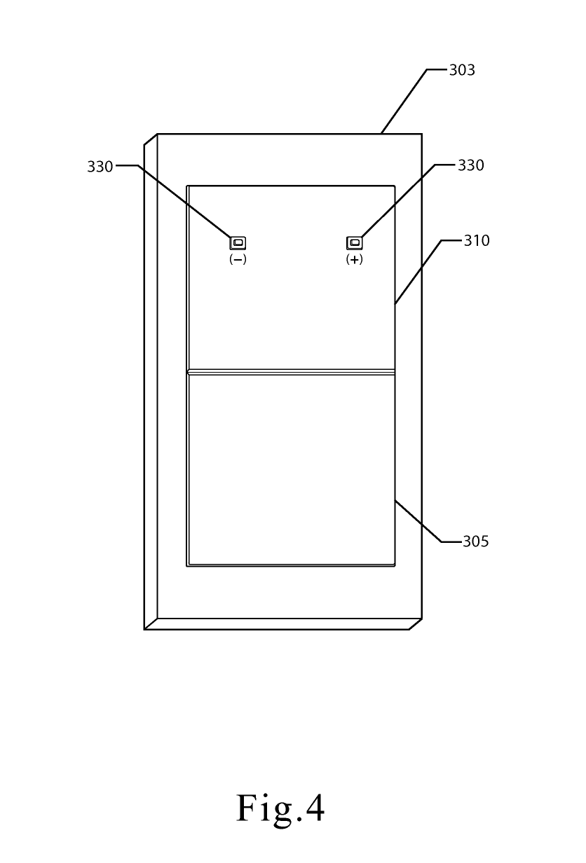

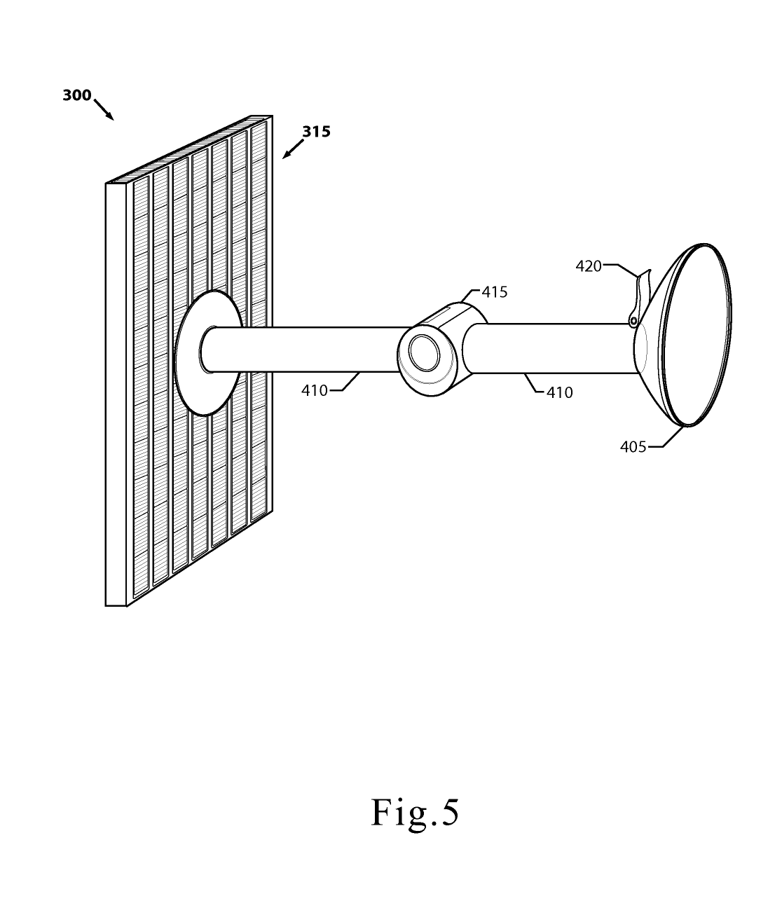

In a preferred embodiment, the magnetic mounting platform 300 may comprise a battery 310 (shown in FIG. 4) and a solar panel 315 (shown in FIG. 5). The battery 310 is preferably adapted to receive and store electric current from the solar panel 315 and/or case and power charger of the mobile phone. The solar panel 315 is preferably located behind the magnetic mounting platform 300 and is also preferably used to convert solar energy to electrical energy, which is preferably stored in the battery 310. The case 200 may also be configured to allow the electrical energy stored in the battery to be transferred to the mobile phone 1000.

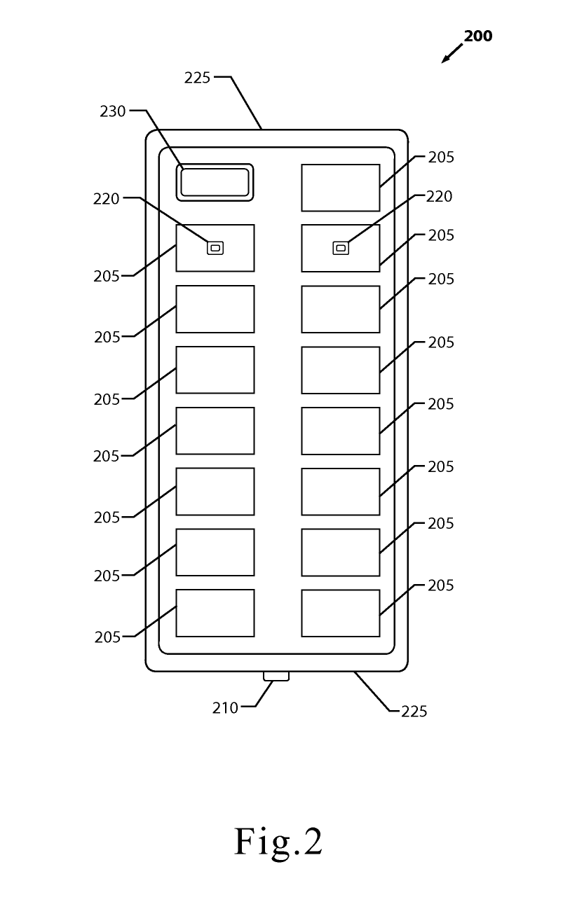

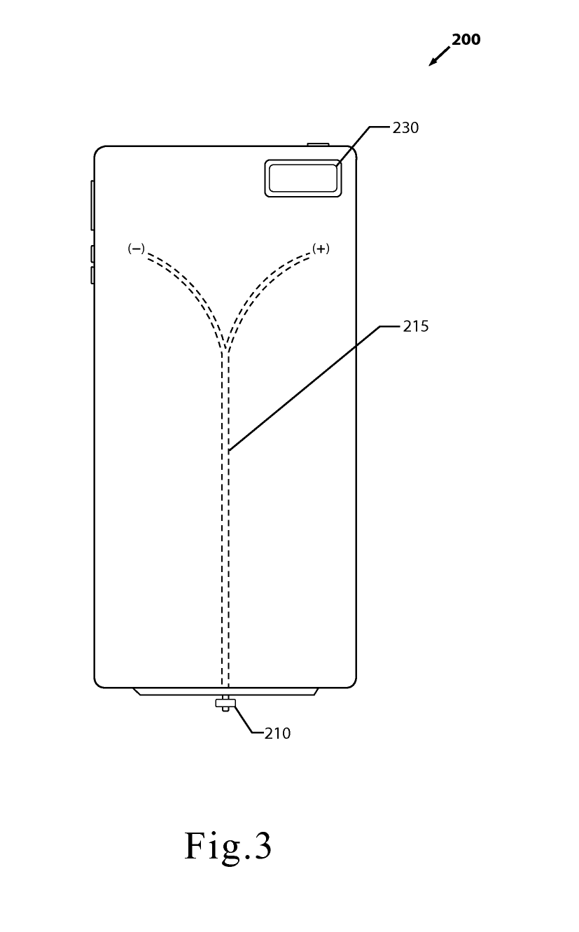

FIG. 2 is an illustration of a front elevational view of one embodiment of a case. As shown in FIG. 2, one embodiment of the case 200 may comprise: one or more metal plates 205, a charging port 210, one or more wires 215 (shown in FIG. 3), and one or more first charging contacts 220. The charging port 210 may be configured to allow a power cable connector to mate and engage with the case 200 and/or mobile phone 1000 in order to allow battery charging of the mobile phone 1000. This will preferably allow transfer of electrical current from the charging port 210 to the first charging contacts 220 via wires 215. In one embodiment, the charging port 210 may protrude outside the case by approximately by 15 millimeters. The charging contacts 220 may then preferably apply an electrical current from the charging port 210 (or magnetic mounting platform 300) to the mobile phone 1000 when the mobile phone 1000 is connected to the case 200. Preferably, the first charging contacts 220 protrude from the inner portion of the case 200 and/or metal plates 205. Preferably, the first charging contacts 220 are positioned in the case, such that the charging contacts 220 may provide an electrical charge to the battery of the mobile phone 1000. In one embodiment, the first charging contacts 220 may be located at a position that may directly contact the mobile phone, such that the first charging contacts 220 electrically couple with the battery of the mobile phone. In another embodiment, the first charging contacts may be coupled to a connector configured for connecting to the mobile phone (e.g., micro-USB) that attaches to the mobile phone for charging. Specifically, the charging contacts 220 may be coupled to a male micro-USB connector that mates with the female connector of the mobile phone when the mobile phone is housed within the case 200. The metal plates 205 are preferably disposed throughout the case 200 and may function as ferromagnetic material for attracting one or more magnets (i.e., preferably the magnet 305 of the magnetic mounting platform 300), such that the entire case 200 may be held and secured magnetically. In one embodiment, as shown in FIG. 2, the metal plates 205 are preferably arranged in columns, but may be arranged in any manner. The case 200 may also comprise any number of metal plates 205 such as one, two, or ten.

In various embodiments, the case 200 may be constructed in various shapes and sizes to fit and house the mobile phone 1000. For example, the case 200 may be shaped to be substantially the same size as the mobile phone 1000, such that the rim 225 of the case 200 may substantially cover the outer perimeter of the mobile phone 1000. In one embodiment, the sleeve of the case 200 may be between approximately 3 millimeters and 7 millimeters in thickness. The case 200 is preferably constructed of polymers and/or metals, but may be constructed of any type of material. In various embodiments, the case 200 may also comprise a camera hole 230 to provide visible access to the camera of the mobile phone 1000 for capturing images and video on the mobile phone 1000.

The case 200 may comprise metal plates 205 for magnetically securing the case 200 to the magnetic mounting platform 300. In one embodiment, the case 200 may comprise fifteen metal plates 205, for distributing the magnetic attraction throughout the case 200, as shown in FIG. 2. This will preferably to increase and distribute the magnetic attraction and help anchor the case 200 onto the magnetic mounting platform 300. The metal plates 205 are also preferably visible and positioned deep within the case 200, but in various embodiments, the metal plates 205 may be substantially hidden within the case 200. The metal plates 205 are preferably rectangular but may be in any size and shape, and, in a preferred embodiment, each of the metal plates may be between approximately 15 millimeters and 25 millimeters in length and between approximately 12 millimeters and 17 millimeters in width. Although FIG. 2 shows fifteen metal plates 205, the case 200 may comprise any number of metal plates such as one, ten, or fourteen.

FIG. 3 is an illustration of a rear elevational view of one embodiment of a case. As shown in FIG. 3, one embodiment of the case 200 may comprise: a charging port 210 and one or more wires 215. As discussed above, the charging port 210 may be configured to mate and engage a power cable of a phone charger for charging the mobile phone 1000. This configuration may allow a connector of the power cable to transfer electrical current from the charging port 210 to the first charging contacts 220 via wires 215. The wires 215 are preferably standard positive and negative wires to allow electrical current to transfer from the charging port 210 to the first charging contacts 220 and are preferably hidden within the case. In an alternative embodiment, the wires 215 may also be substantially visible on the case 215. The case 200 may also comprise additional wires to provide additional data or information from the mobile phone 1000 to the charging port 210. The camera hole 230 may also be used to provide visible access to the camera for capturing images and videos.

FIG. 4 is an illustration of a front elevational view of one embodiment of the magnetic mounting platform. As shown in FIG. 4, one embodiment of the magnetic mounting platform 300 may comprise: a frame 303, battery 310, solar panel 315 (shown in FIG. 5), and magnet 305. The frame 303 is generally a housing configured to hold and store the battery 310 and magnet 305 and is typically approximately the same size as the case 200 and/or mobile phone 1000. The magnet 305 is preferably any device or piece of an object that exhibits properties of magnetism, such as attracting metal plates or aligning itself in an external magnetic field. The battery 310 is generally any device consisting of second charging contacts 330 and one or more cells, in which chemical energy is converted into electricity and used as a source of power. Preferably, the battery 310 of the magnetic mounting platform 300 may be used to supplement charging power for the mobile phone 1000 and is rechargeable. The magnet 305 may be larger than the battery 310 to help attract and secure the case 200 to the magnetic mounting platform 300. As discussed above, the battery 310 preferably comprises second charging contacts 330 to allow the battery 310 of the magnetic mounting platform 300 to be in electrical communication with the battery of the mobile phone 1000. The solar panel 315 may be a panel designed to absorb the sun's rays as a source of energy for generating electricity and convert that energy to electrical energy for the battery 310 of the magnetic mounting platform 300, which may provide electrical energy for the battery of the mobile phone 1000. The solar panel 315 is preferably located at the rear side of the magnetic mounting platform 300 to allow better exposure to the sun's rays when the magnetic mounting platform 300 is connected to the vehicle mounting arm 400.

In one embodiment, the frame 303 of the magnetic mounting platform 300 may be constructed of a polymer and/or metals and may be in various sizes and shapes. In a preferred embodiment, the frame 303 may be between approximately 3.0 inches and 6.00 inches in length, between approximately 2.0 inch and 3.0 inches in width, and between approximately 10 millimeters and 20 millimeters in thickness. Regarding the battery 310 of the magnetic mounting platform 300, the battery 310 may be between approximately 33 millimeters and 37 millimeters in length. Preferably, the magnetic mounting platform 300 may be larger than the case 200, so that the case 200 will not fall off when attached to the magnetic mounting platform 300. Although FIG. 4 shows a single battery and single magnet, the magnetic mounting platform may store multiple batteries and/or magnets.

FIG. 5 is an illustration of a rear perspective view of one embodiment of the magnetic mounting platform and vehicle mounting arm and shows the magnetic mounting platform attached to the vehicle mounting arm. As shown in FIG. 5, one embodiment of the magnetic mobile phone mounting kit 100 may comprise: a magnetic mounting platform 300 and a vehicle mounting arm 400. As discussed above, the vehicle mounting arm 400 is generally configured to connect and hold the magnetic mounting platform 300, case 200, and mobile phone 1000 onto a vehicle. Specifically, the suction cup 405 is preferably attached to one end of the vehicle mounting arm 400, and is preferably configured to mount or attach onto a windshield or dashboard of a vehicle. The magnetic mounting platform 300 is preferably configured to removeably attach to the second end of the vehicle mounting arm 400 via fasteners such as hook fasteners and may comprise a magnet 305, a battery 310, and a solar panel 315. The magnet 305 is preferably configured to attract the metal plates 205 of the case 200, such that the case 200 may be held and removeably secured to the magnetic mounting platform 300. The battery 310 is preferably configured to receive the electric current from the solar panel 315 and is preferably used to store an electrical charge. FIG. 5 also shows that the solar panel 315 is preferably located behind the magnetic mounting platform 300, such that the solar panel 315 is substantially exposed directly to solar energy when the magnetic mounting platform 300 and vehicle mounting arm 400 are attached to the vehicle windshield/dashboard. The magnetic mounting platform 300 is also preferably used to provide electrical energy stored in the battery 310 of the magnetic mounting platform 300, which in turn may transfer to the case 200 and mobile phone 1000.

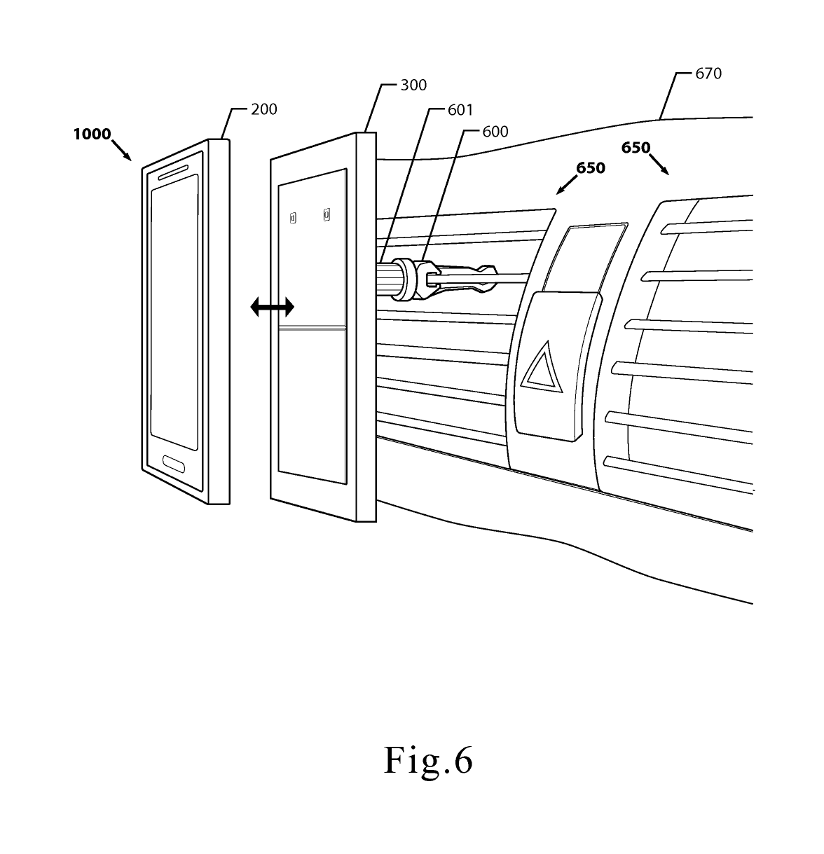

FIG. 6 is an illustration of one embodiment of the vehicle mounting arm with an air vent clip and shows how the mobile phone is mounted onto a vehicle dashboard via the magnetic mounting platform, vehicle mounting arm, and air vent clip. As shown in FIG. 6, one embodiment of the magnetic mobile phone mounting kit 100 may comprise: the case 200, air vent clip 600, vehicle mounting arm 601, and magnetic mounting platform 300. In another embodiment, the air vent clip 600 is another type of device for attaching to a surface and is preferably one or more fasteners configured to hold and secure the vehicle mounting arm 601, magnetic mounting platform 300 and case 200 to a dashboard 670 of a vehicle. Specifically, the air vent clip 600 is preferably configured to attach to the air vents 650 of a vehicle dashboard 670 and may comprise the vehicle mounting arm 601 with an additional fastener on the opposing end for securing the magnetic mounting platform 300 to the vehicle mounting arm 601 and air vent clip 600 (i.e., when the magnetic mounting platform 300 is removed or detached from the vehicle mounting arm 400). The air vent clips 600 is generally constructed of polymers or metals and may be in various sizes and shapes. Thus, once the magnetic mounting platform 300 is attached to the air vent 650 of the vehicle dashboard 670 via the air vent clip 600 and vehicle mounting arm 601, the case 200 and mobile phone 1000 may be mounted onto the air vent 650 of the vehicle's dashboard 670. Although FIG. 6 shows only a single air vent clip 600 attached to the magnetic mounting platform 300, any number of air vent clips may be used to secure the magnetic mounting platform such as two, three, four, and five air vent clips. Additionally, the vehicle mounting arm 601 and air vent clip 600 may be a single piece or may comprise of multiple pieces.

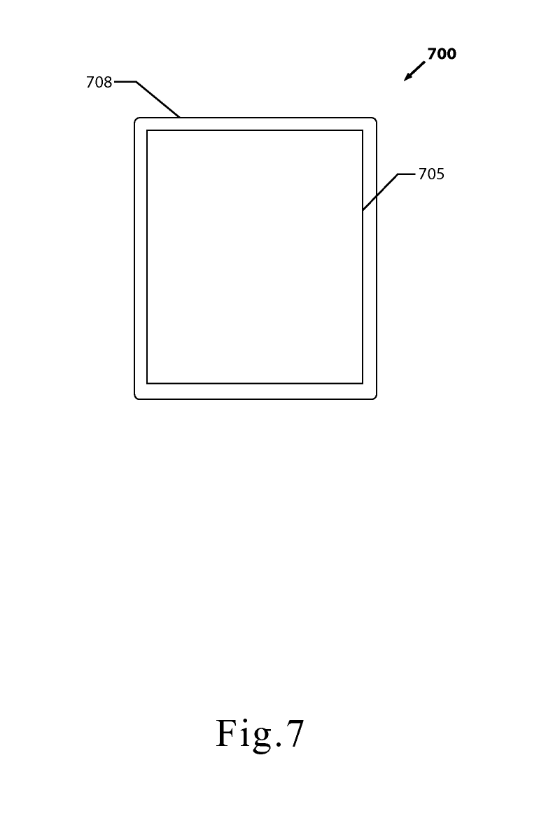

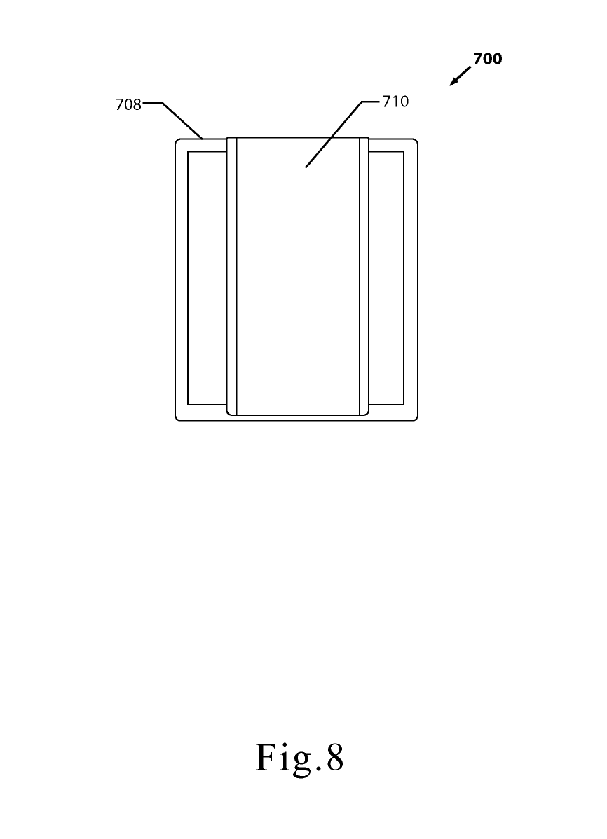

FIG. 7 is an illustration of a front elevational view of one embodiment of a holster. As shown in FIG. 7, one embodiment of the magnetic mobile phone mounting kit 100 may comprise a holster 700, wherein the holster 700 may comprise a magnet 705, housing 708, and a clip 710 (shown in FIG. 8). The holster 700 is generally a handsfree holder worn on a belt or other article clothing and is preferably used for carrying and securing the mobile phone 1000 via magnetism. The holster 700 may also comprise a receptacle for holding and securing the mobile phone 1000. The clip 710 is preferably used to attach and secure the magnetic holster to a belt of a user. The housing 708 may be used to house the magnet 705 and the magnet 705 is preferably used to attract, hold, and secure the mobile phone case and mobile phone 1000.

In one embodiment, the holster 700 may be constructed of leather and may be between 45 millimeters and 55 millimeters in length, between approximately 30 millimeters and 40 millimeters in width, and between approximately 10 millimeters and 15 millimeters in thickness. In a preferred embodiment, the holster 700 may be 50 millimeters in length, 35 millimeters in width, and 13 millimeters in thickness. In various embodiments, the magnet 705 may be visible on the holster 700 or may be hidden within the holster 700. The magnet 705 may also be a positioned approximately 1.0 centimeters from the outside perimeter of the holster 700.

FIG. 8 is an illustration of a rear elevational view of one embodiment of a holster. As shown in FIG. 8, one embodiment of the holster 700 may comprise a housing 708 and a clip 710. As discussed above, the clip 710 may be used to attach onto the user's belt, such that the user may hold and carry the mobile phone 1000 around his or her waist. The clip 710 may be in any shape or size, but in a preferred embodiment, the clip 710 may be between approximately 1.50 inches and 3.00 inches in length and approximately 0.5 inch and 1.5 inches in width.

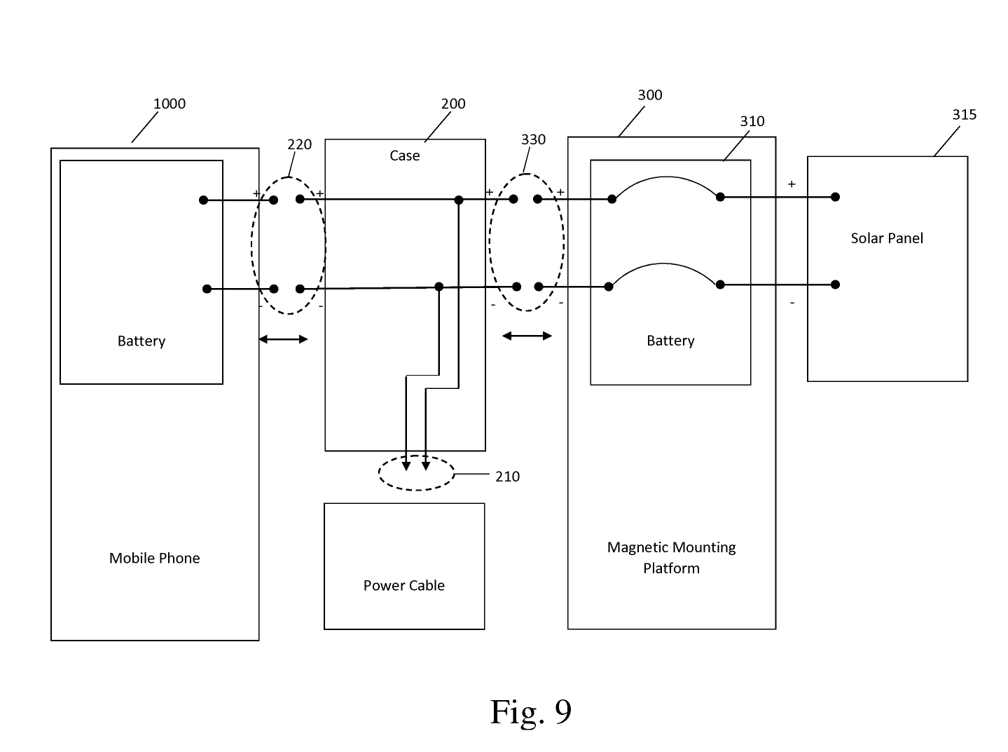

FIG. 9 is a schematic block diagram of the mobile phone mounting kit and shows the possible electrical connections among the mobile phone, case, magnetic mounting platform, and solar panel. As shown in FIG. 9, another embodiment of the mobile phone mounting kit may comprise: a case 200 and magnetic mounting platform 300, wherein the magnetic mounting platform 300 may comprise a solar panel 315. FIG. 9 shows that the solar panel 315 is preferably electrically coupled to the battery 310 of the magnetic mounting kit 300 and may be used to convert the solar power to electrical energy for the battery 310. FIG. 9 also shows that the mobile phone 1000 may be connected and engaged to the case 200, such that the battery of the mobile phone 1000 may be electrically coupled to the first charging contacts 220 of the case 200. The case 200 may be configured to be electrically coupled to the battery 310 of the magnetic mounting platform 300, such that the case 200 and perhaps the battery of the mobile phone 1000 may couple to the second charging contacts 330. This configuration may allow the energy created from the solar panel 315 to transfer first to the battery 310 of the magnetic mounting platform 300 and then to the case 200. The electrical energy transferred to the case 200 may later transfer to the battery of the mobile phone 1000, if the mobile phone 1000 is connected to the case 200 and magnetic mounting platform 300. Finally, FIG. 9 also shows that a charging port 210 may be used to provide electrical power from the power cable to the first charging contacts 220 of the case 200.

While the foregoing written description of the disclosure enables one of ordinary skill to make and use what is considered presently to be the best mode thereof, those of ordinary skill will understand and appreciate the existence of variations, combinations, and equivalents of the specific embodiment, method, and examples herein. The disclosure should therefore not be limited by the above described embodiment, method, and examples, but by all embodiments and methods within the scope and spirit of the disclosure as claimed.

The foregoing description of the preferred embodiment of the disclosure has been presented for the purposes of illustration and description. While multiple embodiments are disclosed, still other embodiments of the present disclosure will become apparent to those skilled in the art from the above detailed description, which shows and describes illustrative embodiments of the disclosure. As will be realized, the disclosure is capable of modifications in various obvious aspects, all without departing from the spirit and scope of the present disclosure. Accordingly, the detailed description is to be regarded as illustrative in nature and not restrictive. Also, although not explicitly recited, one or more embodiments of the disclosure may be practiced in combination or conjunction with one another. Furthermore, the reference or non-reference to a particular embodiment of the disclosure shall not be interpreted to limit the scope the disclosure. It is intended that the scope of the disclosure not be limited by this detailed description, but by the claims and the equivalents to the claims that are appended hereto.

Except as stated immediately above, nothing which has been stated or illustrated is intended or should be interpreted to cause a dedication of any component, step, feature, object, benefit, advantage, or equivalent to the public, regardless of whether it is or is not recited in the claims.

What is claimed is:

1. A mobile phone mounting kit, comprising:
a case;
a magnetic mounting platform; and
a vehicle mounting arm;
wherein said magnetic mounting platform is configured to removeably attach to a first end of said vehicle mounting arm;
wherein said second end of said vehicle mounting arm comprises a device for attaching to a surface;
wherein said magnetic mounting platform comprises at least one magnet; and
wherein said case is configured to removeably engage with a mobile phone and comprises one or more metal plates for attaching and securing to said at least one magnet of said magnetic mounting platform, such that said case securely but removeably attaches to said magnetic mounting platform.

2. The mobile phone mounting kit of claim 1, wherein said case further comprises:
a charging port;
one or more wires; and
at least two first charging contacts;
wherein a first end of said one or more wires are coupled to said charging port;
wherein a second end of said one or more wires are coupled to said at least two first charging contacts;
wherein said at least two first charging contacts are configured to couple with a battery of said mobile phone when said case is engaged with said mobile phone, such that said at least two first charging contacts are in electrical communication with said battery of said mobile phone; and
wherein said charging port is configured to matingly engage with a connector of a power cable for charging said mobile phone by transferring an electrical current from said charging port to said at least two first charging contacts via said one or more wires.

3. The mobile phone mounting kit of claim 2, wherein said magnetic mounting platform further comprises a battery;
wherein said battery of said magnetic mounting platform comprises at least two second charging contacts;
wherein said at least two second charging contacts are configured to couple with said at least two first charging contacts of said case when said case is mounted on said magnetic mounting platform, such that said at least two second charging contacts are in electrical communication with said at least two first charging contacts; and
wherein said battery of said magnetic mounting platform is configured to store an electrical charge for said mobile phone.

4. The mobile phone mounting kit of claim 3, wherein said magnetic mounting platform further comprises a solar panel;
wherein said solar panel is positioned at a rear side of said magnetic mounting platform and is in electrical communication with said battery of said magnetic mounting platform, such that said solar panel is configured to charge said battery of said magnetic mounting platform.

5. The mobile phone mounting kit of claim 1, wherein said surface is an air vent of a vehicle dashboard;
wherein said device for attaching to said surface is one or more air vent clips;
wherein a distal end of said one or more air vent clips is configured to removeably attach to said vehicle mounting arm; and
wherein a proximal end of said one or more air vent clips is configured to removeably attach to said air vent, such that said mobile phone may be mounted onto said air vent of said vehicle dashboard when said mobile phone is attached to said case and said magnetic mounting platform.

6. The mobile phone mounting kit of claim 1, wherein said device for attaching to said surface is a suction cup.

7. The mobile phone mounting kit of claim 1, wherein each of said one or more metal plates of said case is between approximately 15 millimeters and 25 millimeters in length and between approximately 12 millimeters and 17 millimeters in width.

8. The mobile phone mounting kit of claim 4, wherein said battery of said magnetic mounting platform is between approximately 33 millimeters and 37 millimeters in width and between approximately 10 millimeters and 15 millimeters in thickness.

9. A mobile phone mounting kit, comprising:
a case;
a magnetic mounting platform; and
a vehicle mounting arm;
wherein said magnetic mounting platform is configured to removeably attach to a first end of said vehicle mounting arm;
wherein said second end of said vehicle mounting arm comprises a device for attaching to a surface;
wherein said magnetic mounting platform comprises at least one magnet;
wherein said case is configured to removeably engage with a mobile phone and comprises one or more metal plates for attaching and securing to said at least one magnet of said magnetic mounting platform, such that said case securely but removeably attaches to said magnetic mounting platform; and
wherein at least one of said one or more metal plates are hidden within said case.

10. The mobile phone mounting kit of claim 9, wherein said case comprises:
a charging port;
one or more wires; and
at least two first charging contacts;
wherein a first end of said one or more wires are coupled to said charging port;
wherein a second end of said one or more wires are coupled to said at least two first charging contacts;
wherein said at least two first charging contacts are configured to couple with a battery of said mobile phone when said case is engaged with said mobile phone, such that said at least two first charging contacts are in electrical communication with said battery of said mobile phone;
wherein said charging port is configured to matingly engage with a connector of a power cable for charging said mobile phone by transferring an electrical current from said charging port to said at least two first charging contacts via said one or more wires; and
wherein said one or more wires are hidden within said case.

11. The mobile phone mounting kit of claim 10, wherein said magnetic mounting platform further comprises a battery;
wherein said battery of said magnetic mounting platform comprises at least two second charging contacts;
wherein said at least two second charging contacts are configured to couple with said at least two first charging contacts of said case when said case is mounted on said magnetic mounting platform, such that said at least two second charging contacts are in electrical communication with said at least two first charging contacts; and
wherein said battery of said magnetic mounting platform is configured to store an electrical charge for said mobile phone.

12. The mobile phone mounting kit of claim 11, wherein said magnetic mounting platform further comprises a solar panel;
wherein said solar panel is positioned at a rear side of said magnetic mounting platform and is in electrical communication with said battery of said magnetic mounting platform, such that said solar panel is configured to charge said battery of said magnetic mounting platform.

13. The mobile phone mounting kit of claim 12, wherein said surface is an air vent of a vehicle dashboard;
wherein said device for attaching to said surface is one or more air vent clips;
wherein a distal end of said one or more air vent clips is configured to removeably attach to said vehicle mounting arm; and
wherein a proximal end of said one or more air vent clips is configured to removeably attach to said air vent, such that said mobile phone may be mounted onto said air vent of said vehicle dashboard when said mobile phone is attached to said case and said magnetic mounting platform.

14. The mobile phone mounting kit of claim 13, wherein said device for attaching to said surface is a suction cup.

15. The mobile phone mounting kit of claim 9, wherein said vehicle mounting arm comprises a joint configured to move and adjust said vehicle mounting arm;

16. A mobile phone mounting kit, comprising:
a case; and
a holster;
wherein said holster comprises a clip, at least one magnet, and a housing for said at least one magnet;
wherein said clip is configured to fasten onto a belt of a user; and
wherein said case is configured to removeably engage with a mobile phone and comprises one or more metal plates for attaching and securing to said at least one magnet, such that said case securely but removeably attaches to said at least one magnet.

17. The mobile phone mounting kit of claim 18, wherein said housing are constructed of leather.
